(19) United States
(12) Patent Application Publication
(10) Pub. No.: US 2012/0114950 A1
(43) Pub. Date: May 10, 2012

(54) COATED ARTICLE AND METHOD OF MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHUN-MAO LIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/172,219

(22) Filed: Jun. 29, 2011

(30) Foreign Application Priority Data
Nov. 8, 2010 (CN) 201010534912.9

(51) Int. Cl. B32B 15/08; B32B 15/09; C23C 14/35

(52) U.S. Cl. 428/412; 428/457; 428/458; 204/192.14

(57) ABSTRACT

A coated article includes a metal layer coated on a substrate. The substrate is made of plastic with photosensitivity property, and has a plurality of free radicals —O. and —CO. a surface thereof. The metal layer is coated on the substrate. The free radicals link with metal atoms of the metal layer to connect the substrate and the metal layer.

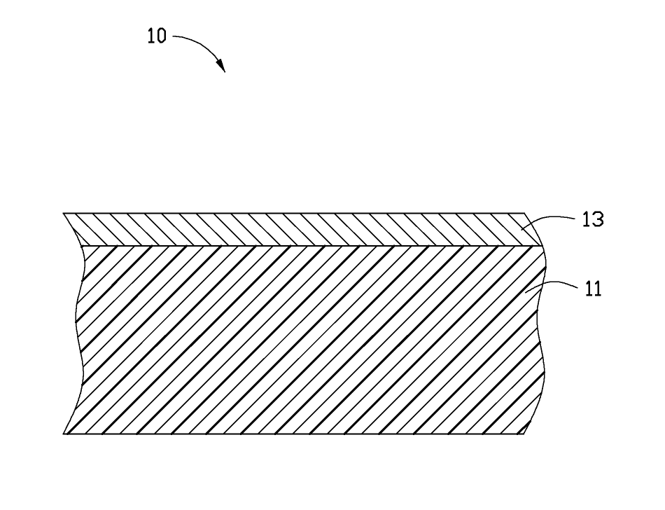

### BACKGROUND

1. Technical Field

This disclosure relates to a coated article and a method of making the same.

2. Description of Related Art

Physical vapor deposition (PVD) is widely used to improve properties of substrates. A plastic substrate coated with a metal layer by PVD has a metallic appearance and good wear resistance. Forming a metal layer on a plastic substrate using PVD is popular in the industry. However, since properties of metal can be quite different from those of the plastic substrate, a binding force between the metal layer and the plastic substrates can be weak, and the metal layer can be easily worn away. One way to improve the binding force between the metal layer and the plastic substrates, is increasing roughness of the binding surface of the plastic substrate by sandblasting. However, sandblasting may not always create enough binding force.

Therefore, there is room for improvement within the art.

### BRIEF DESCRIPTION OF THE DRAWING

Many aspects of the coated article and method of making the same can be better understood with reference to the following drawing. The components in the drawing are not necessarily drawn to scale, the emphasis instead being placed upon clearly illustrating the principles of the coated article and method of making the same.

FIGURE is a cross-section view of a coated article, in accordance with an exemplary embodiment.

### DETAILED DESCRIPTION

FIGURE shows an exemplary embodiment of a coated article 10. The coated article 10 includes a metal layer 13 coated on a plastic substrate 11. The substrate 11 is made of polyester or polycarbonate plastics. The metal layer 13 is made of one of magnesium, zirconium, aluminum and titanium. The plastic substrate 11 is treated to form a plurality of free radicals, e.g., —O. and —CO. on a surface of the substrate 11. The free radicals can react with metal atoms in the metal layer 13 to form chemical bonds. These chemical bonds can increase the binding force between the substrate 11 and the metal layer 13.

A method of making the coated article 10 includes the following steps:

A plastic substrate 11 is provided. The substrate 11 needs to be photosensitive and able to form a plurality of active free radicals, e.g., —O. and —CO. under ultraviolet light. In this exemplary embodiment, the substrate 11 is made of polyester or polycarbonate plastics.

A surface pre-treatment is applied to the substrate 11. The pre-treatment includes oil cleaning, paraffin removal, cleaning by plasma, and drying. In this embodiment, a sodium hydroxide solution or a potassium hydroxide solution is used to clean oil and paraffin off the substrate 11.

A metal layer 13 is formed on the substrate 11 by magnetron sputtering, by a process including a first sputtering process and a second sputtering process. The substrate 11 is set in a vacuum chamber (not shown) of a vacuum sputtering coating machine (not shown).

Before the first sputtering process, the chamber is evacuated until the pressure in the chamber is from about 3.0*10⁻³ pascals (Pa) to about 8.0*10⁻³ Pa. Argon gas is then input into the chamber at a flow of about 300 sccm to about 500 sccm. The purity of the argon gas is 99.9999%. A metal target and an ultraviolet lamp are disposed in the vacuum chamber. The target may be made of one of magnesium, zirconium, aluminum and titanium. The target is activated to sputter metal atoms on a baffle plate positioned in front of the target for about 5 minutes (min) to about 10 min. Thus, impurities or pollutants, such as dust, on the target can be completely removed.

During the first sputtering process, the target and the ultraviolet lamp are activated. Power of the target is adjusted to be in a range of about 1 kilowatt (kw) to about 12 kw. The ultraviolet lamp is configured for applying ultraviolet light. The ultraviolet intensity is in a range of about 10 mv/cm² to about 20 mv/cm². Argon gas is input into the chamber at a flow of about 50 sccm to about 400 sccm. A bias voltage in a range of about −50 V to about −150 V is applied to the substrate 11. A temperature of air in the chamber is in a range of about 50° C. to about 100° C. The ultraviolet light irradiates the substrate 11, and active free radicals, e.g., —O. and —CO. are formed on the surface of the substrate 11 to link with the metal atoms sputtered on the substrate 11. The ultraviolet lamp may be fixed above the chamber, and vertically illuminates the surface of the substrate 11. The time of the first sputtering process is in a range of about 5 min to about 10 min.

During the second sputtering process, the ultraviolet lamp is turned off and the power of the target is adjusted to be about 8 kw to about 12 kw. The other technological parameters remain the same. The time of the second sputtering process is in a range of 5 min to 10 min. The metal layer 13 is formed on the substrate 11 with a thickness about 50 nm to 200 nm.

Free radicals, e.g., —O. and —CO. are very active and react with the active metal atoms, e.g., Mg, Zr, Al, Ti, on the substrate 11 to form chemical bonds. These chemical bonds greatly improve the binding force between the substrate 11 and the metal layer 13.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a substrate made of plastic with photosensitivity property; and
a metal layer coated on the substrate, the metal layer connected to the substrate partially by chemical bonds between metal atoms of the metal layer and a plurality of free radicals —O. and —CO formed on a surface of the substrate.

2. The coated article as claimed in claim 1, wherein the metal layer is made of one of magnesium, zirconium, aluminum and titanium.

3. The coated article as claimed in claim 1, wherein the substrate is made of polyester or polycarbonate plastics.

4. A method of making a coated article, comprising steps of:
providing a substrate plastic with photosensitivity property; and
forming a metal layer on the substrate by magnetron sputtering, including:
a first puttering process, in which metal atoms are sputtered from a metal target to the substrate, power of the target being in arrange of about 1 kw to about 12 kw; a ultraviolet lamp applying ultraviolet light to illuminate the substrate to form a plurality of free radicals —O. and —CO. on the surface of the substrate for linking the metal atoms on the substrate; and
a second sputtering process, the ultraviolet lamp being turn off, power of the target being in arrange of about 8 kw to about 12 kw, the metal layer formed after the second sputtering process.

5. The method as claimed in claim 4, wherein during the first sputtering process, the ultraviolet intensity is in a range of about 10 mv/cm² to about 20 mv/cm².

6. The method as claimed in claim 5, wherein the ultraviolet lamp vertically illuminates the surface of the substrate 11.

7. The method as claimed in claim 4, wherein the time of the first sputtering process is in a range of about 5 min to about 10 min.

8. The method as claimed in claim 4, wherein the time of the second sputtering process is in a range of about 10 min to about 20 min.

9. The method as claimed in claim 4, wherein a thickness of the metal layer is in a range of about 50 nm to about 200 nm.

10. The method as claimed in claim 9, wherein the metal layer is make of one of magnesium, zirconium, aluminum or titanium.

11. The method as claimed in claim 4, wherein during the first and the second sputtering process take place in a chamber, argon gas as a working gas is input into the chamber at a flow of about 50 sccm to about 400 sccm, a bias voltage in a range of about −50 V to about −150 V is applied to the substrate, a temperature of air in the chamber is in a range of about 50° C. to about 100° C.

12. The method as claimed in claim 4, wherein the substrate is made of polyester or polycarbonate plastics.
